(19) United States
(12) Patent Application Publication
(10) Pub. No.: US 2025/0107067 A1
(43) Pub. Date: Mar. 27, 2025

(54) MEMORY DEVICE AND METHOD OF MANUFACTURING THE SAME

(71) Applicant: Samsung Electronics Co., Ltd., Suwon-si (KR)

(72) Inventor: Chaelyoung KIM, Suwon-si (KR)

(73) Assignee: Samsung Electronics Co., Ltd., Suwon-si (KR)

(21) Appl. No.: 18/676,726

(22) Filed: May 29, 2024

(30) Foreign Application Priority Data
Sep. 22, 2023 (KR) 10-2023-0127366

(51) Int. Cl. H10B 12/00

(52) U.S. Cl. CPC H10B 12/315; H10B 12/482; H10B 12/488; H10D 1/714; H10D 1/716

(57) ABSTRACT

A memory device includes a substrate, a unit cell selection transistor on the substrate, and a capacitor structure on the unit cell selection transistor, the capacitor structure comprising a common electrode connected to the unit cell selection transistor, a plurality of plate electrodes facing the common electrode, and a capacitor dielectric layer arranged between the common electrode and the plurality of plate electrodes. The common electrode comprises a vertical extension portion in contact with the unit cell selection transistor and extending in a vertical direction, and a plurality of horizontal extension portions extending in a first horizontal direction from a side wall of the vertical extension portion and apart from each other in the vertical direction. Each of the plurality of plate electrodes extends in a second horizontal direction between the plurality of horizontal extension portions, the second horizontal direction being perpendicular to the first horizontal direction.

### CROSS-REFERENCE TO RELATED APPLICATION

This application is based on and claims priority under 35 U.S.C. § 119 to Korean Patent Application No. 10-2023-0127366, filed on Sep. 22, 2023, in the Korean Intellectual Property Office, the disclosure of which is incorporated by reference herein in its entirety.

### BACKGROUND

The inventive concepts relates to a semiconductor memory device and a method of manufacturing the same.

As miniaturization, multi-functionalization, and high performance of electronic products are required, high-capacity semiconductor memory devices are demanded, and in order to provide the high-capacity semiconductor memory devices, an increased degree of integration is required. A degree of integration of a previous two-dimensional (2D) semiconductor memory device is mainly determined by an area occupied by a unit memory cell. Thus, though the degree of integration of the 2D semiconductor memory device has been increasing, the increase is still limited. Therefore, a three-dimensional (3D) semiconductor memory device for increasing the memory capacity by stacking a plurality of memory cells on a substrate in a vertical direction has been introduced.

### SUMMARY

The inventive concepts provide a memory device having increased integration and reliability.

The inventive concepts provide a method of manufacturing a memory device having increased integration and reliability.

According to various example embodiments of the inventive concepts, there is provided a memory device. The memory device includes a substrate, a unit cell selection transistor on the substrate, and a capacitor structure on the unit cell selection transistor, the capacitor structure comprising a common electrode connected to the unit cell selection transistor, a plurality of plate electrodes facing the common electrode, and a capacitor dielectric layer arranged between the common electrode and the plurality of plate electrodes. The common electrode comprises a vertical extension portion in contact with the unit cell selection transistor and extending in a vertical direction, and a plurality of horizontal extension portions extending in a first horizontal direction from a side wall of the vertical extension portion and apart from each other in the vertical direction. Each of the plurality of plate electrodes extends in a second horizontal direction between the plurality of horizontal extension portions, the second horizontal direction being perpendicular to the first horizontal direction.

According to another aspect of the inventive concept, there is provided a memory device. The memory device includes a substrate, a plurality of bit lines extending on the substrate in a first horizontal direction and apart from each other in a second horizontal direction perpendicular to the first horizontal direction, a plurality of unit cell selection transistors arranged on the plurality of bit lines, respectively, a plurality of common electrodes arranged on the plurality of unit cell selection transistors to be apart from each other in the second horizontal direction, the plurality of common electrodes each comprising a vertical extension portion and a plurality of horizontal extension portions extending in the first horizontal direction from a side wall of the vertical extension portion, a plurality of capacitor dielectric layers encircling the plurality of common electrodes, respectively, and a plurality of plate electrodes respectively facing, with the plurality of capacitor dielectric layers therebetween, the plurality of common electrodes, the plurality of plate electrodes extending in the second horizontal direction and overlapping each other in a vertical direction. Each of the plurality of plate electrodes comprises a first end and a second end that are opposite to each other in the first horizontal direction, wherein the first end has a stepped side wall shape, and the second end has a side wall shape linearly extending in the vertical direction, and the plurality of common electrodes face the first end.

According to another aspect of the inventive concept, there is provided a memory device. The memory device includes a substrate, a bit line extending on the substrate in a first horizontal direction, a plurality of semiconductor patterns arranged on the bit line to be apart from each other in the first horizontal direction, a plurality of word lines covering side surfaces of the plurality of semiconductor patterns, respectively, and extending in a second horizontal direction perpendicular to the first horizontal direction, a plurality of common electrodes arranged on the plurality of semiconductor patterns, wherein each of the plurality of common electrodes comprises a vertical extension portion extending in a vertical direction and a plurality of horizontal extension portions extending in the first horizontal direction from a side wall of the vertical extension portion and apart from each other in the vertical direction, a plurality of plate electrodes, each of the plate electrodes is arranged between the plurality of horizontal extension portions, and extend in the second horizontal direction, and a plurality of capacitor dielectric layers between the plurality of common electrodes and the plurality of plate electrodes. A first common electrode and a second common electrode adjacent to each other in the first horizontal direction, from among the plurality of common electrodes, have mirror symmetrical shapes with respect to each other.

### BRIEF DESCRIPTION OF THE DRAWINGS

Various example embodiments will be more clearly understood from the following detailed description taken in conjunction with the accompanying drawings in which:

FIG. 1 is an equivalent circuit diagram of a memory device according to various example embodiments;

FIG. 2A is a perspective view of main elements of a memory device according to various example embodiments;

FIG. 2B is a plan view of a memory device according to various example embodiments;

FIG. 2C is an enlarged view of a region indicated as “EX1” of FIG. 2B;

FIG. 2D is a cross-sectional view of the region EX1 taken along a line X1-X1′ of FIG. 2C, and FIG. 2E is a cross-sectional view of the region EX1 taken along a line Y1-Y1′ of FIG. 2C;

FIG. 3 is a cross-sectional view for describing a memory device according to some example embodiments;

FIG. 4 is a cross-sectional view for describing a memory device according to some example embodiments;

FIGS. 5A and 5B are an equivalent circuit diagram and a cross-sectional view of a memory device according to some example embodiments;

FIGS. 6A to 13 are plan views and cross-sectional views for describing a method of manufacturing a memory device, according to various example embodiments, wherein FIGS. 7A, 10A, and 11A are plan views showing a portion corresponding to the region indicated as “EX1” of FIG. 2C according to a process order, FIGS. 6A, 7B, 8A, 9, 10B, 11B, 12A, and 13 are cross-sectional views showing a portion corresponding to a cross-section taken along the line X1-X1′ of FIG. 2C according to a process order, and FIGS. 6B, 7C, 8B, 11C, and 12B are cross-sectional views showing a portion corresponding to a cross-section taken along the line Y1-Y1′ of FIG. 2C according to a process order;

FIGS. 14A to 14D are cross-sectional views for describing a method of manufacturing a memory device, according to some example embodiments, and show a portion corresponding to the cross-section taken along the line X1-X1′ of FIG. 2C according to a process order; and

FIG. 15 is a cross-sectional view for describing a method of manufacturing a memory device, according to some example embodiments, and shows a portion corresponding to the cross-section taken along the line X1-X1′ of FIG. 2C.

### DETAILED DESCRIPTION OF THE EMBODIMENTS

Hereinafter, various example embodiments are described in detail with reference to the accompanying drawings. For the same elements on the drawings, the same reference numerals are used, and the descriptions are not repeated.

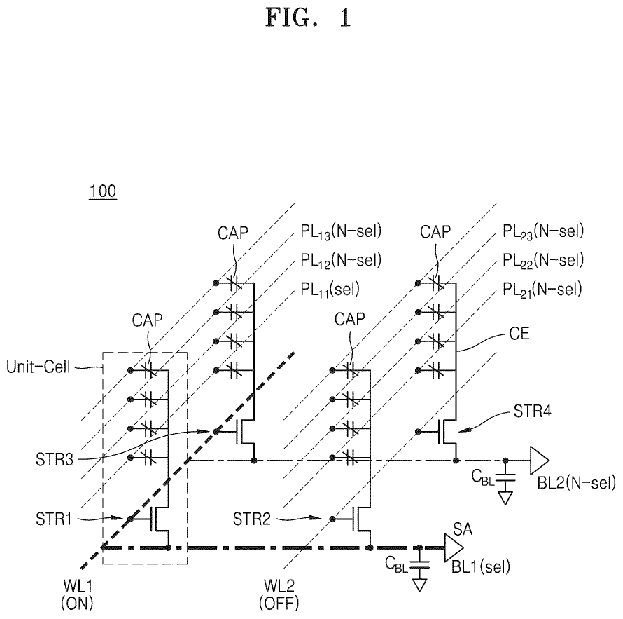

FIG. 1 is an equivalent circuit diagram of a memory device 100 according to various example embodiments.

Referring to FIG. 1, the memory device 100 according to various example embodiments may include a plurality of bit lines BL1 and BL2, a plurality of word lines WL1 and WL2, a plurality of selection transistors STR1, STR2, STR3, and STR4, and a plurality of capacitors CAP. In FIG. 1, it is illustrated that the memory device 100 includes two bit lines BL1 and BL2 and two word lines WL1 and WL2. However, the bit lines and the word lines are not limited thereto, and one bit or word line, or three or more bit or word lines may be included.

According to various example embodiments, the plurality of bit lines BL1 and BL2 and the plurality of word lines WL1 and WL2 may be two-dimensionally arranged, and each of the plurality of selection transistors STR1, STR2, STR3, and STR4 may be formed at a point at which the plurality of bit lines BL1 and BL2 and the plurality of word lines WL1 and WL2 cross each other. For example, and end of a source/drain of a first selection transistor STR1 and an end of a source/drain of a second selection transistor STR2 may be commonly connected to a first bit line BL1. For example, a gate of the first selection transistor STR1 and a gate of the third selection transistor STR3 may be commonly connected to a first word line WL1.

According to various example embodiments, a capacitor column including three capacitors CAP may be connected to the other end of the source/drain of each of the plurality of selection transistors STR1, STR2, STR3, and STR4. According to various example embodiments, one common electrode CE may be connected to the other end of the source/drain of each of the plurality of selection transistors STR1, STR2, STR3, and STR4, and three plate lines may be connected to the one common electrode CE to form one capacitor column.

For example, a first capacitor column may be connected to the other end of the source/drain of the first selection transistor STR1, a second capacitor column may be connected to the other end of the source/drain of the second selection transistor STR2, a third capacitor column may be connected to the other end of the source/drain of the third selection transistor STR3, and a fourth capacitor column may be connected to the other end of the source/drain of the fourth selection transistor STR4.

According to various example embodiments, the first capacitor column and the third capacitor column may share first to third plate lines PL₁₁, PL₁₂, and PL₁₃. According to various example embodiments, the second capacitor column and the fourth capacitor column may share fourth to sixth plate lines PL₂₁, PL₂₂, and PL₂₃.

According to various example embodiments, one selection transistor and one capacitor column connected thereto may form a unit cell. For example, as illustrated in FIG. 1, each of the plurality of selection transistors STR1 to STR4 may be connected to the three capacitors CAP to form the unit cell. However, the inventive concepts are not limited thereto. Each capacitor column may include one, two, or four or more capacitors CAP.

The memory device 100 according to various example embodiments may have the connection relationship described above and may have a structure in which a plurality of capacitors CAP, for example, three capacitors CAP are connected to one selection transistor. Accordingly, the memory device 100 may also be referred to as having a 1TnC structure, indicating that n (n is an integer that is 2 or greater) capacitors Cap are connected to one transistor Tr. For reference, in the circuit diagram of FIG. 1, as indicated by thick dotted lines and thick two-dot chain lines, the first bit line BL1 and the first word line WL1 may be selected to turn on the first selection transistor STR1, and the first bit line BL1 and the first plate line PL₁₁ may be selected to store or read information in or from the corresponding capacitor CAP. In the case of reading, a sense amplifier (SA) connected to the first bit line BL1 may be used. In the circuit diagram of FIG. 1, sel may denote a selected line and N-sel may denote non-selected lines.

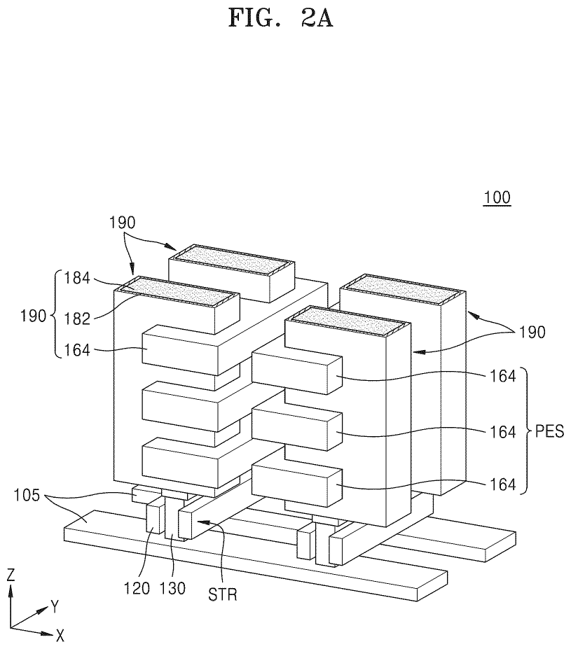

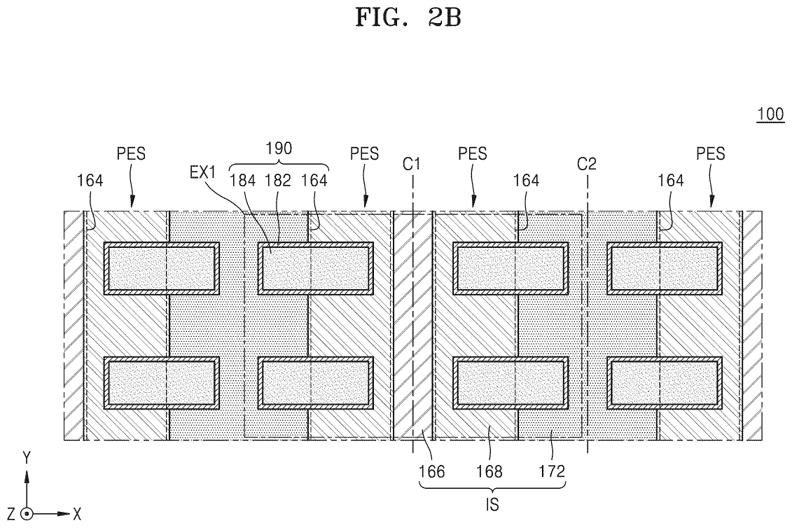

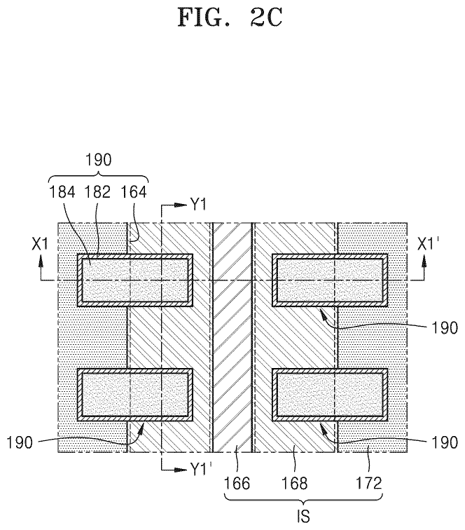

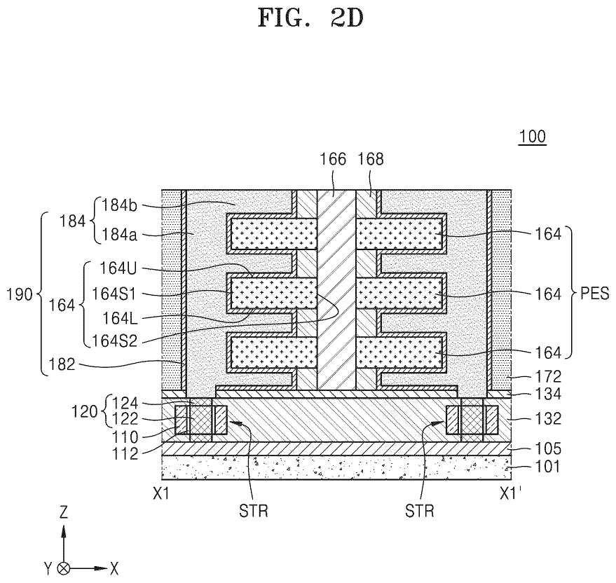

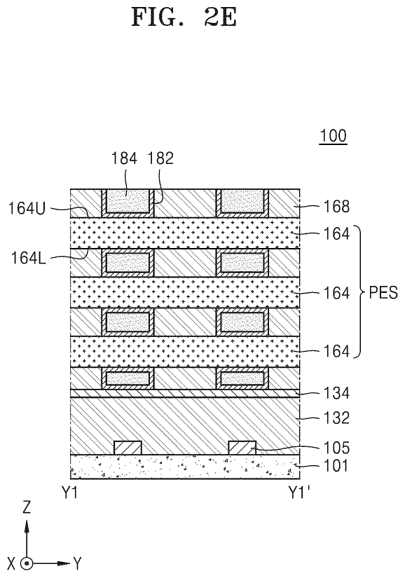

FIG. 2A is a perspective view of main elements of the memory device 100 according to various example embodiments. FIG. 2B is a plan view of the memory device 100 according to various example embodiments. FIG. 2C is an enlarged view of a region of FIG. 2B, indicated as “EX1.” FIG. 2D is a cross-sectional view of the region EX1 taken along a line X1-X1′ of FIG. 2C, and FIG. 2E is a cross-sectional view of the region EX1 taken along a line Y1-Y1′ of FIG. 2C. Hereinafter, descriptions are given by referring to FIG. 1 together, and aspects that are described above with reference to FIG. 1 are briefly described or are not described.

In this specification, a vertical direction may be defined as a Z direction, and a horizontal direction may be defined as a direction perpendicular to the Z direction. A first horizontal direction and a second horizontal direction may be defined as directions crossing each other. The first horizontal direction may be referred to as an X direction, and the second horizontal direction may be referred to as a Y direction. In this specification, a vertical level may refer to a height level in the vertical direction (the Z direction).

Referring to FIGS. 2A to 2E, the memory device 100 according to various example embodiments may include a plurality of selection transistors STR arranged on a substrate 101 and a plurality of capacitor structures 190 arranged on the plurality of selection transistors STR, respectively. For example, one capacitor structure 190 may be connected onto one selection transistor STR to form one unit cell (see FIG. 1). In this specification, the selection transistor STR may be referred to as a unit cell selection transistor. The plurality of unit cells may have a mirror shape symmetrical structure with respect to a virtual first central line C1 or a virtual second central line C2 illustrated in FIG. 2B.

According to various example embodiments, the memory device 100 may include a plurality of bit lines 105 extending on the substrate 101 in the first horizontal direction (the X direction), a plurality of semiconductor patterns 120 arranged on the plurality of bit lines 105, a plurality of word lines 110 facing the plurality of semiconductor patterns 120 with a gate dielectric layer 112 therebetween and extending in the second horizontal direction (the Y direction) perpendicular to the first horizontal direction (the X direction), and the capacitor structure 190 on the plurality of semiconductor patterns 120.

According to some example embodiments, the substrate 101 may include Si, for example, single-crystalline Si, poly-crystalline Si (poly-Si), or non-crystalline Si. However, materials of the substrate 101 are not limited to Si. For example, the substrate 101 may include a group IV semiconductor such as Ge, a groups IV-IV compound semiconductor such as SiGe or SiC, or a groups III-V compound semiconductor such as GaAs, InAs, InP, or the like. However, example embodiments are not limited thereto.

According to some example embodiments, the substrate 101 may be based on a Si-bulk substrate. Also, the substrate 101 may be based on a silicon-on-insulator (SOI) substrate or a germanium-on-insulator (GeOI) substrate. The substrate 101 is not limited to the bulk substrate, the SOI substrate, or the GeOI substrate and may be based on an epitaxial wafer, a polished wafer, an annealed wafer, etc. The substrate 101 may include a conductive area, for example, a well doped with impurities, or various structures doped with impurities. Also, the substrate 101 may include a P-type substrate or an N-type substrate according to a type of doped impurity ions. Although not shown, a peripheral circuit and an interconnect layer connected to the peripheral circuit may be arranged on some portions of the substrate 101.

According to various example embodiments, the plurality of bit lines 105 may be arranged to be apart from each other in the second horizontal direction (the Y direction). For example, the plurality of bit lines 105 may include a doped polysilicon layer, a metal layer, or a combination thereof. However, example embodiments are not limited thereto. For example, each of the plurality of bit lines 105 may include W, but is not limited thereto. In this specification, the plurality of bit lines 105 may correspond to the bit lines BL1 and BL2 of FIG. 1.

According to various example embodiments, the plurality of semiconductor patterns 120 may be arranged on the plurality of bit lines 105, respectively, to be apart from each other in the first horizontal direction (the X direction). According to some example embodiments, a first group of the plurality of semiconductor patterns 120 may be arranged on the bit line 105, and a second group of the plurality of semiconductor patterns 120 may be arranged on another bit line 105, wherein the first group and the second group may be apart from each other in the second horizontal direction (the Y direction). For example, the selection transistors STR arranged in the first horizontal direction (the X direction) may share one bit line 105.

According to various example embodiments, the plurality of semiconductor patterns 120 may include a channel area 122 and impurity areas 124 arranged at both ends of the channel area 122 in the vertical direction (the Z direction). For example, the impurity area 124 arranged at a lower end of the channel area 122 may be in contact with the bit line 105, and the impurity area 124 arranged at an upper end of the channel area 122 may be in contact with the capacitor structure 190.

According to various example embodiments, each of both side walls of the channel area 122 may face the word line 110 with the gate dielectric layer 112 therebetween. In FIGS. 2A and 2D, it is illustrated that a pair of word lines 110 cover both side walls of one channel area 122 and extend in the second horizontal direction (the Y direction). However, the plurality of word lines 110 are not limited thereto. For example, each of the plurality of word lines 110 may have a gate all around structure to surround omnidirectional side surfaces of the channel area 122 and may extend in the second horizontal direction (the Y direction). According to some example embodiments, a third group of the plurality of semiconductor patterns 120 may face one of the word lines 110, and a fourth group of the plurality of semiconductor patterns 120 may face another word line 110, wherein the third group and the fourth group may be apart from each other in the first horizontal direction (the X direction). For example, each of the semiconductor patterns 130 of the first group may be connected to different bit lines 105. For example, the selection transistors STR arranged in the second horizontal direction (the Y direction) may share a pair of word lines 110.

According to some example embodiments, the plurality of word lines 110 may include a conductive material. The word lines 110 may include, for example, at least one of a doped semiconductor material, a metal, conductive metal nitride, and a metal-semiconductor compound. However, example embodiments are not limited thereto. In this specification, the plurality of word lines 110 may correspond to the word lines WL1 and WL2 of FIG. 1.

According to some example embodiments, the plurality of semiconductor patterns 120 may be arranged at points at which the plurality of bit lines 105 and the plurality of word lines 110 cross each other, and the plurality of semiconductor patterns 120 at the points may form the plurality of selection transistors STR together with the plurality of bit lines 105 and the plurality of word lines 110.

According to some example embodiments, the plurality of semiconductor patterns 120 may include an un-doped semiconductor material or a doped semiconductor material. According to some example embodiments, the semiconductor pattern 120 may include general semiconductor materials, such as single crystalline Si, poly-Si, SiGe, SiC, etc. However, example embodiments are not limited thereto. According to some example embodiments, the semiconductor pattern 120 may include transition metal dichalcogenides (TMD), such as CuS₂, CuSe₂, WSe₂, MoS₂, MoSe₂, WS₂, etc., hexagonal boron nitride (h-BN), graphene, carbon nanotube (CNT), or a two-dimensional (2D) semiconductor material including a combination thereof. However, example embodiments are not limited thereto. According to some example embodiments, the semiconductor pattern 120 may include an amorphous metal oxide semiconductor material, a polycrystalline metal oxide semiconductor material, or a combination thereof. For example, the metal oxide semiconductor material may include at least one of In—Zn-based oxide (IZO), Zn—Sn-based oxide (ZTO), In—Ga-based oxide (IGO), Y—Zn-based oxide (YZO), and In—Ga—Zn-based oxide (IGZO). However, materials of the semiconductor pattern 120 are not limited to the materials described above. According to some example embodiments, the impurity areas 124 may be formed by doping both ends of the semiconductor pattern 120 in the vertical direction (the Z direction), with impurity ions. For example, the impurity areas 124 may form a source junction and a drain junction of the selection transistor STR. Although not shown, for an ohmic contact with a metal, a silicide layer may be formed between the impurity area 124 and the bit line 105 and between the impurity area 124 and a vertical extension portion 184a of the capacitor structure 190, described below. The silicide layer may include, for example, at least one of Ti silicide, W silicide, Co silicide, and Ni silicide. However, example embodiments are not limited thereto.

According to various example embodiments, the memory device 100 may include a lower insulating layer 132 encircling, on the substrate 101, the plurality of bit lines 105, the plurality of semiconductor patterns 120, the gate dielectric layer 112, and the plurality of word lines 110. For example, the plurality of bit lines 105 may be apart from each other in the second horizontal direction (the Y direction) with the lower insulating layer 132 therebetween, and the plurality of word lines 110 may be apart from each other in the first horizontal direction (the X direction) with the lower insulating layer 132 therebetween.

According to various example embodiments, the lower insulating layer 132 and an upper surface of the plurality of semiconductor patterns 120 may be coplanar, for example, an upper surface of the impurity area 124, may be coplanar with the lower insulating layer 132. According to some example embodiments, the lower insulating layer 132 may include oxide, nitride, or a combination thereof, but is not limited to the examples described above.

According to various example embodiments, the memory device 100 may include an etch stop layer 134 arranged on the lower insulating layer 132. According to some example embodiments, the etch stop layer 134 may include silicon nitride, silicon oxide, SiOC, SiOCN, SiCN, SiBN, SiON, SiBCN, SiOF, SiOCH, or a combination thereof. However, example embodiments are not limited thereto.

According to various example embodiments, the plurality of capacitor structures 190 may be arranged on the plurality of selection transistors STR, respectively. The memory device 100 according to various example embodiments may include an insulating structure IS encircling the plurality of capacitor structures 190 on the etch stop layer 134. According to various example embodiments, the plurality of capacitor structures 190 may include a plurality of common electrodes 184, a plurality of plate electrodes 164, and a plurality of capacitor dielectric layers 182 arranged between the plurality of common electrodes 184 and the plurality of plate electrodes 164. Each of the plurality of capacitor structures 190 may correspond to the capacitor column described above with reference to FIG. 1, the common electrode 184 may correspond to the common electrode CE of FIG. 1, and the plurality of plate electrodes 164 may correspond to the plurality of plate lines PL₁₁, PL₁₂, PL₁₃, PL₂₁, PL₂₂, and PL₂₃ of FIG. 1.

According to various example embodiments, the plurality of common electrodes 184 may be arranged on the plurality of selection transistors STR, respectively. According to various example embodiments, each of the plurality of common electrodes 184 may include the vertical extension portion 184a and a plurality of horizontal extension portions 184b extending from a side wall of the vertical extension portion 184a in the first horizontal direction (the X direction). The vertical extension portion 184a may penetrate through the etch stop layer 134 and may be in contact with the upper surface of the semiconductor pattern 120, for example, an upper surface of the impurity area 124. The plurality of horizontal extension portions 184b may be apart from each other in the vertical direction (the Z direction) and may vertically overlap each other. According to various example embodiments, the vertical extension portion 184a and the plurality of horizontal extension portions 184b may be integrally formed in the same process. According to various example embodiments, remaining portions of an outer surface of each of the plurality of common electrodes 184 excluding a lower surface of the vertical extension portion 184a, the lower surface being in contact with the impurity area 124, may be in contact with the capacitor dielectric layer 182 to be surrounded by the capacitor dielectric layer 182. According to some example embodiments, the capacitor dielectric layer 182 may not cover the lower surface and an upper surface of the vertical extension portion 184a and an upper surface of an uppermost of the horizontal extension portions 184b from among the horizontal extension portions 184b connected to the one vertical extension portion 184a.

According to some example embodiments, the plurality of common electrodes 184 may include any one of a semiconductor material, a metal, conductive metal nitride, and conductive metal oxide. Here, the metal may include, for example, ruthenium, iridium, titanium, tantalum, etc. The conductive metal nitride may include titanium nitride, tantalum nitride, niobium nitride, tungsten nitride, etc. The conductive metal nitride may include iridium oxide, niobium oxide, etc. However, materials of the plurality of common electrodes 184 are not limited to the materials described above.

According to various example embodiments, the plurality of plate electrodes 164 may be apart from each other in the first horizontal direction (the X direction) and the vertical direction (the Z direction) and may extend in the second horizontal direction (the Y direction). According to various example embodiments, three plate electrodes 164 from among the plurality of plate electrodes, the three plate electrodes 164 overlapping each other in the vertical direction (the Z direction), may form one plate stack PES, and the plurality of plate stacks PES may be apart from each other in the first horizontal direction (the X direction). FIGS. 2A, 2D, and 2E illustrate that each plate stack PES includes three plate electrodes 164. However, the plate stack PES is not limited thereto. For example, each plate stack PES may include two or four or more plate electrodes 164 overlapping each other in the vertical direction (the Z direction).

According to various example embodiments, each of the plurality of plate stacks PES may extend in the second horizontal direction (the Y direction) and may face the common electrodes 184 arranged in the second horizontal direction (the Y direction) from among the plurality of common electrodes 184. For example, a first group of the plurality of common electrodes 184 may be arranged in the second horizontal direction (the Y direction), and the first group may face a plate stack PES from among the plurality of plate stacks PES. For example, the capacitor structures 190 arranged in the second horizontal direction (the Y direction) may share one plate stack PES.

According to various example embodiments, each of the plurality of plate electrodes 164 may be arranged between the plurality of horizontal extension portions 184b apart from each other in the vertical direction (the Z direction). For example, each of the plurality of horizontal extension portions 184b may be arranged between a lowermost of the plate electrodes 164 of the plate stack PES and the etch stop layer 134, between two plate electrodes 164 adjacent to each other in the vertical direction (the Z direction), and on an upper surface of an uppermost of the plate electrodes 164 of the plate stack PES. For example, a horizontal extension portion 184b selected from among the plurality of horizontal extension portions 184b may extend in the first horizontal direction (the X direction) between the two plate electrodes 164 adjacent to each other in the vertical direction (the Z direction).

According to some example embodiments, the plurality of horizontal extension portions 184b of the common electrodes 184 may vertically overlap a first portion of the plate stack PES extending in the second horizontal direction (the Y direction) and may cover the first portion. The plurality of horizontal extension portions 184b of another common electrode 184 in the second horizontal direction (the Y direction) may vertically overlap a second portion of the plate stack PES and may cover the second portion. A third portion between the first portion and the second portion may be covered by the insulating structure IS. For example, the third portion may vertically overlap the insulating structure IS and may be encircled by the insulating structure IS.

According to some example embodiments, each of an upper surface 164U and a lower surface 164L of each of the plate electrodes 164 of the plate stack PES may include a portion facing the horizontal extension portion 184b of the common electrode 184. For example, a plate electrode 164 selected from among the plate stack PES may have a structure to be sandwiched by two of the horizontal extension portions 184b adjacent to each other in the vertical direction (the Z direction). On one of the plate electrodes 164, one of the horizontal extension portions 184b may be apart from another horizontal extension portion 184b with a plate electrode 164 therebetween, and one of the horizontal extension portions 184b being arranged below the plate electrode 164. A lower surface of a horizontal extension portion 184b may face the upper surface 164U of a plate electrode 164 with the capacitor dielectric layer 182 therebetween. An upper surface of the one of the horizontal extension portions 184b may face the lower surface 164L of one of the plate electrodes 164 with the capacitor dielectric layer 182 therebetween. According to some example embodiments, the plate electrodes 164 of the plate stack PES and the plurality of horizontal extension portions 184b of the common electrode 184 may be arranged at different vertical levels from each other. For example, one of the horizontal extension portions 184b may be arranged at a higher vertical level than one of the plate electrodes 164, and another horizontal extension portion 184b may be arranged at a lower vertical level than another plate electrode 164. According to some example embodiments, each of the plurality of horizontal extension portions 184b may alternately overlap each of the plurality of plate electrodes 164 in the vertical direction (the Z direction).

According to some example embodiments, a side wall of the vertical extension portion 184a of a common electrode 184 in the first horizontal direction (the X direction) may include facing portions facing a plate stack PES. According to some example embodiments, the plate electrodes 164 of the plate stack PES may include a first side wall 164S1 and a second side wall 164S2 in the first horizontal direction (the X direction), wherein the first side wall 164S may face the side wall of the vertical extension portion 184a with the capacitor dielectric layer 182 therebetween. According to some example embodiments, each of the facing portions of the vertical extension portion 184a may face a side wall of the plate stack PES in the first horizontal direction (the X direction) (for example, the first side walls 174S1), between the plurality of horizontal extension portions 184b. For example, the first side walls 164S1 of the plate stack PES may face the side wall of the vertical extension portion 184a with the capacitor dielectric layer 182 therebetween.

According to some example embodiments, each of the plurality of common electrodes 184 may have a comb structure, and the plurality of plate stacks PES may have a structure interlocked between comb teeth. The plurality of horizontal extension portions 184b of each common electrode 184 may correspond to the comb teeth. According to some example embodiments, each of the plurality of plate stacks PES may be interlocked with groups of the common electrodes 184 arranged in the second horizontal direction (the Y direction). For example, two of the common electrodes 184 arranged in the second horizontal direction (the Y direction) may be interlocked with a plate stack PES.

According to some example embodiments, a first length, which is a length of the plurality of horizontal extension portions 184b in the first horizontal direction (the X direction), may be less than a second length, which is a length of the plurality of plate electrodes 164 in the first horizontal direction (the X direction). According to some example embodiments, each of the plurality of plate electrodes 164 may include a first end and a second end in the first horizontal direction (the X direction). For example, the first end may face the vertical extension portion 184a. According to some example embodiments, ends of the plurality of horizontal extension portions 184b may not be aligned with the second ends of the plurality of plate electrodes 164 in the vertical direction (the Z direction). For example, the second ends of the plurality of plate electrodes 164 may not vertically overlap the plurality of horizontal extension portions 184b.

According to some example embodiments, the capacitor dielectric layer 182 may include ferroelectric materials. Ferroelectric materials have ferroelectricity maintaining spontaneous polarization with an internal electric dipole moment aligned even without an electric field being applied thereto from the outside. Ferroelectric materials have the characteristics in which a polarization (or electric field) value semi-permanently remains in the material even when a predetermined or dynamically determined voltage is applied thereto and then the voltage becomes 0V again. Based on the hysterisis characteristics due to dielectric polarization of the ferroelectric materials, each capacitor may store information of [0] or [1].

According to some example embodiments, the capacitor dielectric layer 182 may include at least one oxide selected from among Hf, Si, Al, Zr, Y, La, Gd, and Sr. For example, the capacitor dielectric layer 182 may include at least one selected from among HfO, HfON, HfSiON, HfZrO, HfTiO, and Si:HfO. However, example embodiments are not limited thereto. The capacitor dielectric layer 182 may further include a dopant according to necessity. The dopant may include at least one element selected from among Si, Al, Zr, Y, La, Gd, Sc, Sr, Mg, and Ba, but example embodiments are not limited thereto. In this specification, “HfO,” “ZrO,” and “HfZrO” denote materials including elements included in respective terms and are not chemical formulas indicating stoichiometric relationships. In this specification, the capacitor dielectric layer 182 may be referred to as a ferroelectric layer.

According to some example embodiments, the capacitor dielectric layer 182 may include a single layer or multiple layers. When the capacitor dielectric layer 182 includes multiple layers, both outermost layers may include ferroelectric thin layers. For example, the capacitor dielectric layer 182 may have a three-layer structure including a first ferroelectric thin layer, an AlO thin layer, and a second ferroelectric thin layer. Also, the capacitor dielectric layer 182 may include a five-layer structure including a first ferroelectric thin layer, a first AlO thin layer, a second ferroelectric thin layer, a second AlO thin layer, and a third ferroelectric thin layer. However, the multi-layered structure of the capacitor dielectric layer 182 is not limited to the three-layer or the five-layer structure described above.

According to various example embodiments, a plurality of capacitors may be formed at interlocking portions of the plurality of common electrodes 184 and the plurality of plate stacks PES. For example, based on the concept of a capacitor, one capacitor may be formed per plate electrode 164. For example, to be precise, in each capacitor structure 190, one of the horizontal extension portions 184b facing the upper surface 164U of one of the plate electrodes 164 of the plate stack PES, and another horizontal extension portion 184b facing the lower surface 164L of one of the plate electrodes 164, the vertical extension portion 184a facing the first side wall 164S1 of the plate electrode 164, and the capacitor dielectric layer 182 between the plate electrode 164 and the portions of the common electrode 184 facing the plate electrode 164 may form one capacitor CAP (see FIG. 1). For example, one common electrode 184 and one capacitor dielectric layer 182 may meet three of the plate electrodes 164 to form three capacitors CAP. For example, three capacitors CAP may be connected to one semiconductor pattern 120 or selection transistor STR. However, the memory device 100 is not limited thereto. The memory device 100 may include the plate stack PES including n plate electrodes 164, wherein n is an integer that is 2 or greater. The memory device 100 according to embodiments may have a structure in which n capacitors CAP are connected to one selection transistor STR. Thus, the memory device 100 according to the present example embodiments may have a 1TrnCap structure, that is, a 1TnC structure.

According to various example embodiments, the insulating structure IS may include an insulation cut pattern 166, a plurality of insulation support patterns 168, and an insulating block 172.

According to some example embodiments, the insulation cut pattern 166 may extend on the etch stop layer 134 in the second horizontal direction (the Y direction), and, in a plan view, may include the first central line C1 of FIG. 2B. According to some example embodiments, the insulation cut pattern 166 may extend in the vertical direction (the Z direction), and each of both side walls of the insulation cut pattern 166 in the first horizontal direction (the X direction) may be in contact with the plate stack PES and the plurality of insulation support patterns 168. For example, the insulation cut pattern 166 may include a portion in contact with the second side wall 164S2 of the plurality of plate electrodes 164. According to some example embodiments, the plurality of insulation support patterns 168 may be apart from each other in the vertical direction (the Z direction) with the plurality of plate electrodes 164 therebetween. For example, each of the plate electrodes 164 overlapping each other in the vertical direction (the Z direction) may be alternately arranged with each of the plurality of insulation support patterns 168 in the vertical direction (the Z direction).

According to some example embodiments, the plurality of insulation support patterns 168 may be arranged at the same vertical level as the plurality of horizontal extension portions 184b. For example, each of the plurality of insulation support patterns 168 may be arranged at the same vertical level as one horizontal extension portion 184b selected from among the plurality of horizontal extension portions 184b.

According to some example embodiments, the insulating block 172 may cover the vertical extension portion 184a of the plurality of common electrodes 184 on the etch stop layer 134 and may include the second central line C2 of FIG. 2B in a plan view. According to some example embodiments, the vertical extension portion 184a may include a first side wall toward the plurality of horizontal extension portions 184b and a second side wall opposite to the first side wall in the first horizontal direction (the X direction). According to some example embodiments, the second side wall of the vertical extension portion 184a may face the insulating block 172 with the capacitor dielectric layer 182 therebetween. According to some example embodiments, both side walls of the vertical extension portion 184a in the second horizontal direction (the Y direction) may face the insulating block 172.

According to some example embodiments, the common electrodes 184 arranged in the second horizontal direction (the Y direction) from among the plurality of common electrodes 184 may form a common electrode array. For example, the plurality of common electrodes 184 may include a plurality of common electrode arrays apart from each other in the first horizontal direction (the X direction). For example, the plurality of common electrode arrays may be apart from each other in the first horizontal direction with the insulation cut pattern 166 or the insulating block 172 therebetween.

According to some example embodiments, the common electrodes 184 included in a first common electrode array may be apart from each other in the second horizontal direction (the Y direction) with the insulating block 172 and the plurality of insulation support patterns 168 therebetween. For example, the insulating block 172 may include a first portion extending in the first horizontal direction between the common electrodes 184 of the first common electrode array. According to some example embodiments, as illustrated in FIG. 2B, each of the plurality of insulation support patterns 168 may include, in the first horizontal direction (the X direction), a first portion facing the plurality of common electrodes 184 and a second portion facing the insulating block 172. According to some example embodiments, the second portion of each of the plurality of insulation support patterns 168 may face each of the plurality of horizontal extension portions 184b in the first horizontal direction (the X direction) and may vertically overlap an end that is in contact with the insulation cut pattern 166 among both ends of the plurality of plate electrodes 164 in the first horizontal direction (the X direction), which overlap each other in the vertical direction (the Z direction). For example, a width of the first portion of each of the plurality of insulation support patterns 168 in the first horizontal direction (the X direction) may be less than a width of the second portion of each of the plurality of insulation support patterns 168 in the first horizontal direction (the X direction). FIG. 2D illustrates the first portion of the plurality of insulation support patterns 168, and FIG. 2E illustrates the second portion of the plurality of insulation support patterns 168. According to some example embodiments, both side walls of the plurality of horizontal extension portions 184b in the second horizontal direction (the Y direction) may face the insulating structure IS, in detail, the first portion of the insulating block 172 and the second portion of the plurality of insulation support patterns 168. According to some example embodiments, a boundary at which the first portion of the insulating block 172 and the second portion of the plurality of insulation support patterns 168 are in contact with each other may be on the side wall of the plurality of horizontal extension portions 184b in the second horizontal direction (the Y direction).

According to some example embodiments, two of the common electrodes 184 from among the plurality of common electrodes 184, being apart from each other in the first horizontal direction (the X direction) with the insulation cut pattern 166 therebetween, may have a mirror shape symmetrical structure. For example, an end of the plurality of horizontal extension portions 184b of one common electrode 184 may face an end of the plurality of horizontal extension portions 184b of another common electrode 184. For example, a plate stack PES interlocked with a common electrode 184 may face the first side wall of the vertical extension portion 184a the common electrode 184, and another plate stack PES interlocked with another common electrode 184 may face the second side wall of the vertical extension portion 184a of the common electrode 184, wherein the first side wall and the second side wall may face each other. In this case, the two plate stacks PES and the may be respectively in contact with both side walls of the insulation cut pattern 166 in the first horizontal direction (the X direction).

According to some example embodiments, each of the insulation cut pattern 166, the insulation support pattern 168, and the insulating block 172 may include silicon nitride, silicon oxide, SiOC, SiOCN, SiCN, SiBN, SION, SiBCN, SiOF, SiOCH, or a combination thereof.

According to some example embodiments, the insulating structure IS may include a material different from a material of the etch stop layer 134. According to some example embodiments, the insulation cut pattern 166 may include a material different from a material of the insulating block 172. According to some example embodiments, the insulation support pattern 168 may include a material different from a material of the insulating block 172.

The memory device 100 according to various example embodiments may include a structure in which the plate stack PES is interlocked with the common electrode 184 as described above. For example, the horizontal extension portion 184b may be arranged between the plurality of plate electrodes 164 apart from each other in the vertical direction (the Z direction). For example, the upper surface 164U, the lower surface 164L, and the first side wall 164S1 of each of the plurality of plate electrodes 164 may face the common electrode 184 with the capacitor dielectric layer 182 therebetween. Accordingly, with respect to a limited volume of the memory device 100, the capacitor capacity/performance may be improved and a memory window (MW) per unit area may be greatly increased. Also, in comparison with a VS-DRAM structure according to a comparative embodiment, in the memory device 100 according to various example embodiments, only the selection transistor S-Tr may be arranged, and an individual cell transistor may not be arranged for each vertical level at which each plate electrode 164 is arranged. Thus, the memory device 100 may be greatly advantageous in terms of the process difficulty/distribution aspects. Also, in the memory device 100 according to various example embodiments, the plate electrodes 164 included in one plate stack PES may be apart from each other in the vertical direction (the Z direction). Accordingly, a read disturb problem due to an integral structure in which the plate electrodes 164 are connected to each other may be resolved, so as to improve the reliability of the memory device 100.

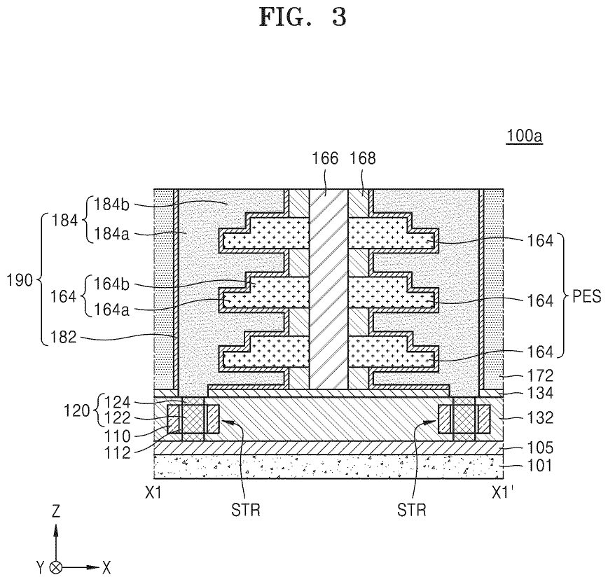

FIG. 3 is a cross-sectional view for describing a memory device 100a according to some example embodiments. In FIG. 3, reference numerals which are the same as the reference numerals of FIGS. 1 and 2A to 2E refer to the same members, and descriptions with respect thereto are not repeatedly given herein.

Referring to FIG. 3, a width of each of the plurality of plate electrodes 164 in the first horizontal direction (the X direction) may not be constant as each of the plurality of plate electrodes 164 extends in the vertical direction (the Z direction). According to various example embodiments, each of the plurality of plate electrodes 164 may include a plurality of portions having different widths in the first horizontal direction (the X direction) from each other, in a direction away from an upper surface of the etch stop layer 134. According to some example embodiments, a first end of each of the plurality of plate electrodes 164 in the first horizontal direction (the X direction) may have a side wall linearly extending in the vertical direction (the Z direction). According to some example embodiments, the first end may be in contact with the insulation cut pattern 166. According to some example embodiments, a second end of each of the plurality of plate electrodes 164, the second end being opposite to the first end in the first horizontal direction (the X direction), may include a protruding portion. According to some example embodiments, the second end may have a stepped side wall. According to some example embodiments, the second end may face the common electrode 184.

According to some example embodiments, each of the plurality of plate electrodes 164 may include a lower portion 164a and an upper portion 164b on the lower portion 164a. According to some example embodiments, the lower portion 164a and the upper portion 164b may have different widths from each other in the first horizontal direction (the X direction).

According to some example embodiments, the lower portion 164a may have a first horizontal width, which is a width in the first horizontal direction (the X direction), and the upper portion 164b may have a second horizontal width, which is a width in the first horizontal direction (The X direction). According to some example embodiments, the first horizontal width of the lower portion 164a may be greater than the second horizontal width of the upper portion 164b.

According to some example embodiments, a side wall of the lower portion 164a in the first horizontal direction (the X direction) and a side wall of the upper portion 164b in the first horizontal direction (the X direction) may be co-planar with each other. For example, the side wall of the lower portion 164a and the side wall of the upper portion 164b may form a side wall of each of the plurality of plate electrodes 164. According to some example embodiments, the lower portion 164a may extend from the other side wall of the upper portion 164b in the first horizontal direction (the X direction), and the lower portion 164a may have a length in the first horizontal direction (the X direction) which is greater than a length of the upper portion 164b in the first horizontal direction (the X direction). For example, the other side wall that is opposite to the side wall of each of the plurality of plate electrodes 164 in the first horizontal direction (the X direction) may have a stepped shape. According to some example embodiments, a portion of an upper surface of the upper portion 164b of one of the plate electrodes 164 and the other side wall of the upper portion 164b may face one of the horizontal extension portions 184b selected from among the plurality of horizontal extension portions 184b. An upper surface of a portion of the lower portion 164a of one of the plate electrodes 164, the portion not vertically overlapping the upper portion 164b, may face the horizontal extension portion 184b. The other side wall of the lower portion 164a of the plate electrode 164 may face the vertical extension portion 184a, and a lower surface of the lower portion 164a may face another horizontal extension portion 184b selected from among the plurality of horizontal extension portions 184b and apart from other horizontal extension portions 184b in the vertical direction (the Z direction) with the plate electrode 164 therebetween. According to some example embodiments, the horizontal extension portions 184b may include a portion arranged at the same vertical level as the upper portion 164b.

FIG. 3 illustrates that the plurality of plate electrodes 164 may include two portions having different widths from each other in the first horizontal direction (the X direction), for example, the lower portion 164a and the upper portion 164b. However, the plurality of plate electrodes 164 are not limited thereto. For example, the plurality of plate electrodes 164 may have three or more portions having different widths from one another in the first horizontal direction (the X direction). In this case, an end of the plurality of plate electrodes 164 in the first horizontal direction may have a side wall including a plurality of protruding portions and/or a plurality of bent portions.

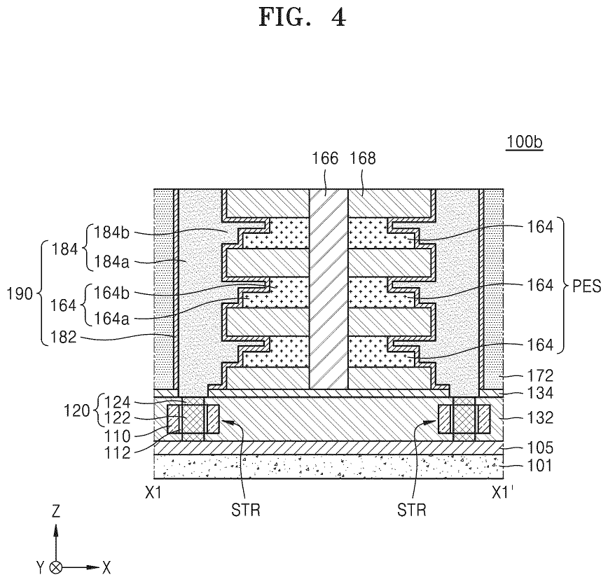

FIG. 4 is a cross-sectional view for describing a memory device 100b according to some example embodiments. In FIG. 4, reference numerals which are the same as the reference numerals of FIGS. 1, 2A to 2E, and 3 refer to the same members, and descriptions with respect thereto are not repeatedly given herein. Hereinafter, a difference between the memory device 100b described with reference to FIG. 4 and the memory device 100a described above with reference to FIG. 3 may be whether or not each of the plurality of horizontal extension portions 184b is arranged at the same vertical level as one selected from among the plurality of plate electrodes 164.

Referring to FIG. 4, the plurality of horizontal extension portions 184b may not cover a lower surface of the lower portion 164a of the plurality of plate electrodes 164 and an upper surface of the upper portion 164b of the plurality of plate electrodes 164. According to some example embodiments, each of the plurality of horizontal extension portions 184b and each of the plurality of plate electrodes 164 facing each of the plurality of horizontal extension portions 184b at the same level may be sandwiched by the plurality of insulation support patterns 168. For example, the upper surface of the upper portion 164b of a plate electrode 164 selected from among the plurality of plate electrodes 164 may be in contact with a lower surface of one of the insulation support patterns 168 selected from among the plurality of insulation support patterns 168. An upper surface of a horizontal extension portion 184b selected from among the plurality of horizontal extension portions 184b and facing the one of the plate electrodes 164, may face the lower surface of one of the insulation support patterns 168 with the capacitor dielectric layer 182 therebetween. The lower surface of the lower portion 164a of one of the plate electrodes 164 may be in contact with an upper surface of another one of the insulation support patterns 168 selected from among the plurality of insulation support patterns 168 and apart from the other insulation support patterns 168 in the vertical direction (the Z direction) with a plate electrode 164 therebetween. A lower surface of the horizontal extension portion 184b may face the insulation support pattern 168 with the capacitor dielectric layer 182 therebetween. According to some example embodiments, a side wall having a stepped shape of both side walls of the plate electrode 164 in the first horizontal direction (the X direction) may face an end of the horizontal extension portion 184b. For example, each of a side wall of the lower portion 164a and a side wall of the upper portion 164b, included in the stepped side wall of the plate electrode 164, may face the horizontal extension portion 184b.

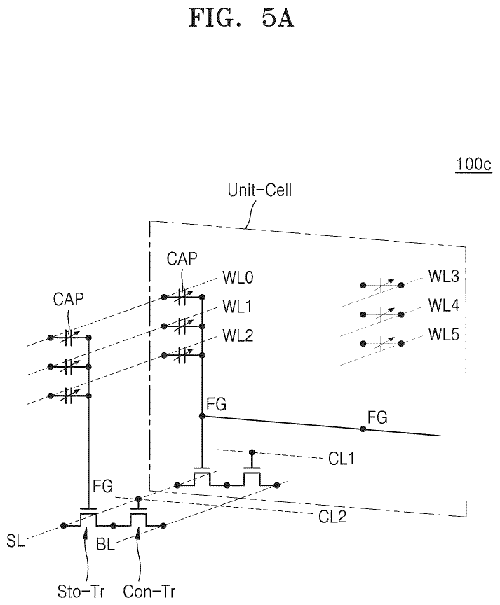

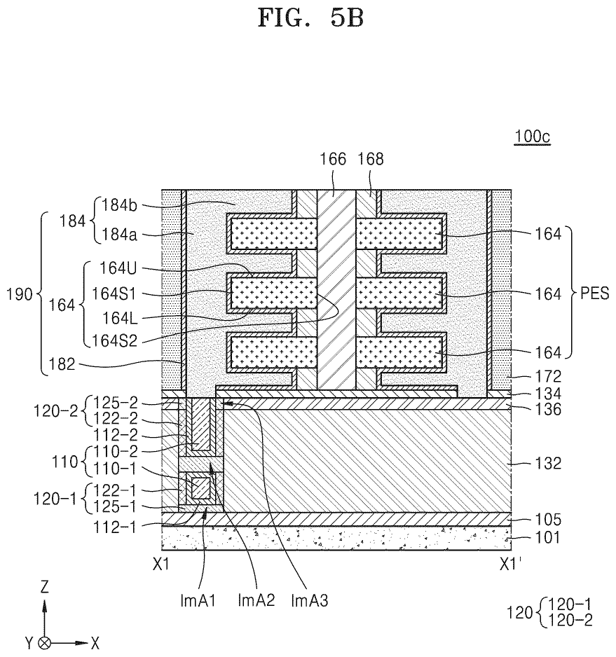

FIGS. 5A and 5B are an equivalent circuit diagram and a cross-sectional view of a memory device 100c according to some example embodiments. In FIGS. 5A and 5B, reference numerals which are the same as the reference numerals of FIGS. 1 and 2A to 2E refer to the same members, and descriptions with respect thereto are not repeatedly given herein.

Referring to FIGS. 5A and 5B, the memory device 100c may be different from the memory device 100 of FIGS. 2A to 2E, in terms of a structure of the word line 110 and the semiconductor pattern 120 corresponding to the word line 110 and an additionally arranged source line 136. In detail, in the memory device 100c according to the present embodiment, aspects of the bit line 105, the capacitor structure 190, and the etch stop layer 134 may be the same as described with respect to the memory device 100 of FIGS. 2A to 2E. However, as the capacitor structure 190 (for example, a capacitor column of FIG. 5A) is connected to a floating gate FG 120-2 of a storage transistor Sto-Tr, capacitors CAP may be additionally connected, through the floating gate FG, as indicated by a light substantial line and dotted lines in FIG. 5A. The capacitors CAP added through the connection of the floating gate FG may also be included in a unit cell Unit-Cell. In addition, FIG. 5A illustrates that word lines WL0, WL1, and WL2 are connected to the capacitors CAP, wherein the word lines WL0, WL1, and WL2 may correspond to the plate line electrode PL of the circuit diagram of the memory device 100 of FIG. 1, in terms of a circuit connection aspect. Thus, the word lines WL0, WL1, and WL2 may correspond to the plate electrodes 164 forming one plate stack PES, in FIG. 5B.

Each of the plurality of word lines 110 may include a lower word line 110-1 and an upper word line 110-2. The lower word lines 110-1 may extend in the second horizontal direction (the Y direction) and may be arranged to be apart from each other in the first horizontal direction (the X direction). That is, the lower word lines 110-1 may be arranged to have substantially the same structure as the word lines 110 of the memory device 100 of FIG. 2D. The lower word line 110-1 may form a control transistor Con-Tr together with a lower semiconductor pattern 120-1. Accordingly, the lower word line 110-1 may be referred to as a control word line.

The upper word line 110-2 may be arranged above the lower word line 110-1 and, in a plan view, may be arranged at a position at which the lower word line 110-1 and the bit line 105 cross each other. An upper surface of the upper word line 110-2 may be connected to the vertical extension portion 184a of the common electrode 184. The upper word line 110-2 may form the storage transistor Sto-Tr together with an upper semiconductor pattern 120-2. Also, power is not connected to the upper word line 110-2, and thus, the upper word line 110-2 may be in a floated state. Thus, the upper word line 110-2 may be referred to as a floating gate FG.

The semiconductor pattern 120 may include the lower semiconductor pattern 120-1 and the upper semiconductor pattern 120-2. The lower semiconductor pattern 120-1 may include a lower channel area 122-1 and a lower impurity area 124-1. Also, the upper semiconductor pattern 120-2 may include an upper channel area 122-2 and an upper impurity area 124-2.

A lower gate dielectric layer 112-1 may be arranged between the lower channel areas 122-1, and the lower channel areas 122-1 may be arranged at both sides of the lower word line 110-1 in the first horizontal direction (the X direction). The lower impurity areas 124-1 may be arranged at both sides of the lower channel area 122-1 in the vertical direction (the Z direction). For example, the lower impurity area 124-1 may include a first impurity area ImA1 arranged below the lower channel area 122-1 and a second impurity area ImA2 arranged above the lower channel area 122-1.

An upper gate dielectric layer 112-2 may be arranged between the upper channel areas 122-2, and the upper channel areas 122-2 may be arranged to surround the upper word line 110-2. The upper impurity areas 124-2 may be arranged at both sides of the upper channel area 122-2 in the vertical direction (the Z direction). For example, the upper impurity area 124-2 may include a second impurity area ImA2 arranged below the upper channel area 122-2 and a third impurity area ImA3 arranged above the upper channel area 122-2, in the z direction. The second impurity area ImA2 may correspond to a shared impurity area commonly used as the lower impurity area 124-1 and the upper impurity area 124-2.

The source lines 136 may extend in the first horizontal direction (the X direction) in parallel with the bit line 105 and may be arranged to be apart from each other in the second horizontal direction (the Y direction). The source line 136 may be connected to the upper semiconductor pattern 120-2. In detail, the source line 136 may be connected to the third impurity area ImA3 of the upper semiconductor pattern 120-2. Accordingly, the source line 136 may be arranged at an upper portion of the upper word line 110-2 directly below the etch stop layer 134.

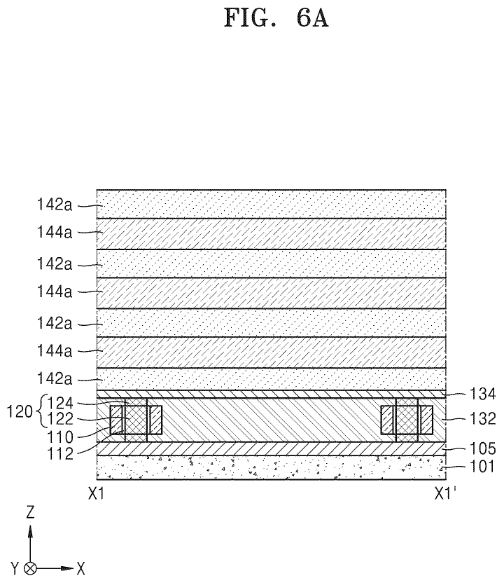

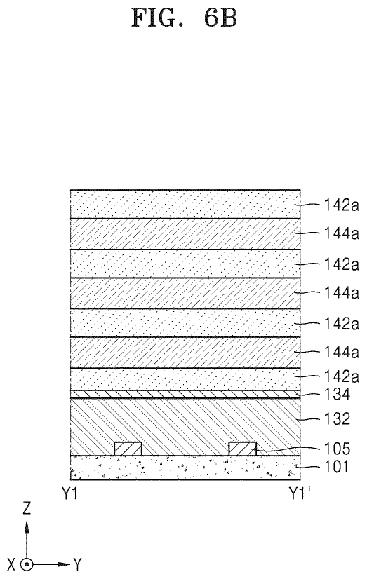

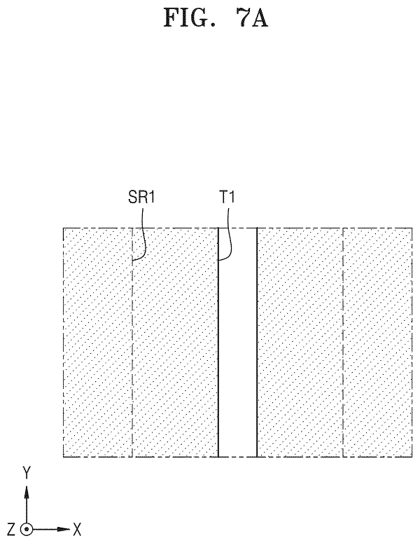

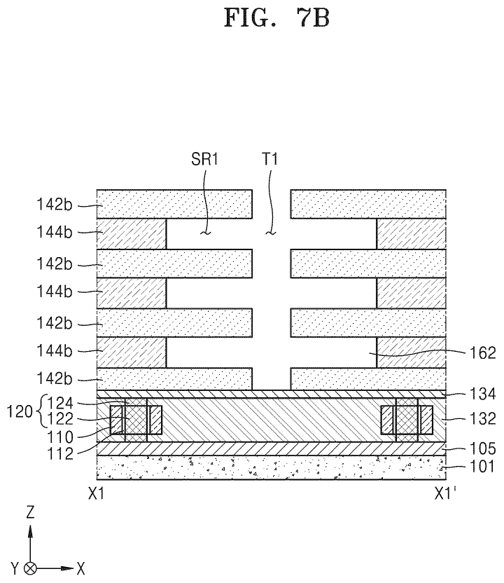

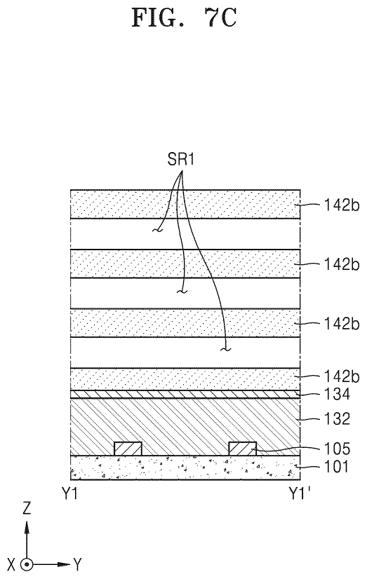

FIGS. 6A to 13 are plan views and cross-sectional views for describing a method of manufacturing a memory device, according to embodiments, wherein FIGS. 7A, 10A, and 11A are plan views showing a portion corresponding to the region indicated as “EX1” of FIG. 2C according to a process order, FIGS. 6A, 7B, 8A, 9, 10B, 11B, 12A, and 13 are cross-sectional views showing a portion corresponding to a cross-section taken along the line X1-X1′ of FIG. 2C according to a process order, and FIGS. 6B, 7C, 8B, 11C, and 12B are cross-sectional views showing a portion corresponding to a cross-section taken along the line Y1-Y1′ of FIG. 2C according to a process order. In FIGS. 6A to 13, reference numerals which are the same as the reference numerals of FIGS. 1 and 2A to 2E refer to the same members, and descriptions with respect thereto are not repeatedly given herein.

Referring to FIGS. 6A and 6B, the method of manufacturing the memory device 100, according to various example embodiments, may include, after first forming, on the substrate 101, the plurality of bit lines 105, the plurality of word lines 110, the gate dielectric layer 112, the plurality of semiconductor patterns 120, and the lower insulating layer 132, forming the etch stop layer 134 covering an upper surface of the lower insulating layer 132 and an upper surface of the semiconductor pattern 120. For example, the etch stop layer 134 may be arranged on the entire surface of the substrate 101.

Thereafter, each of a plurality of first insulating layers 142a and each of a plurality of first sacrificial layers 144a may be alternately stacked on an etch stop layer 105a. The plurality of first insulating layers 142a and the plurality of first sacrificial layers 144a may include materials having etch selectivities with respect to each other. For example, the plurality of first insulating layers 142a may include silicon oxide layers, and the plurality of first sacrificial layers 144a may include silicon nitride layers, but the plurality of first insulating layers 142a and the plurality of first sacrificial layers 144a are not limited thereto. The etch stop layer 134 may include a material having etch selectivities with respect to the plurality of first insulating layers 142a and the plurality of first sacrificial layers 144a.

Referring to FIGS. 7A to 7C, by forming a first trench T1 and a first horizontal recess SR1 on a product of FIGS. 6A and 6B, a plurality of preliminary insulating patterns 142b and a plurality of first sacrificial patterns 144b may be formed.

According to some example embodiments, the first trench T1 may be formed through a dry etch process, after forming a mask pattern (not shown) on the product of FIGS. 6A and 6B. For example, the first trench T1 may have a predetermined width in the first horizontal direction (the X direction) and may penetrate through the plurality of first insulating layers 142a and the plurality of first sacrificial layers 144a in the vertical direction (the Z direction) to expose an upper surface of the etch stop layer 134.

Thereafter, the first horizontal recess SR1 may be formed by removing a portion of the plurality of first sacrificial layers 144a exposed through the first trench T1. That is, for example, the first horizontal recess SR1 may be formed through a wet etch process but is not limited to the example described above. For example, an upper surface and a lower surface of the plurality of preliminary insulating patterns 142b may be exposed through the first horizontal recess SR1.

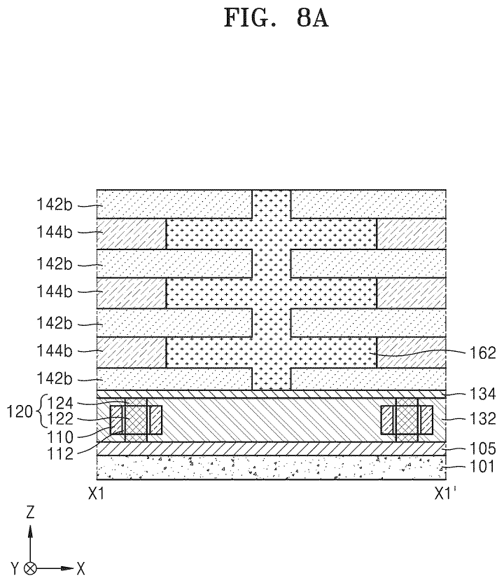

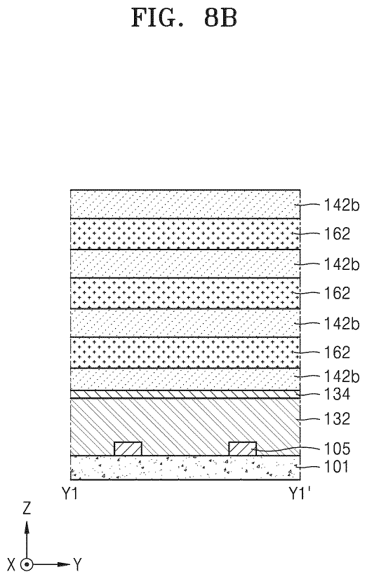

Referring to FIGS. 8A and 8B, the first trench T1 and the first horizontal recess SR1 may be filled with a conductive gap-fill layer 162, in a product of FIGS. 7A to 7C. For example, the conductive gap-fill layer 162 may include a doped polysilicon layer, a metal layer, or a combination thereof. However, example embodiments are not limited thereto.

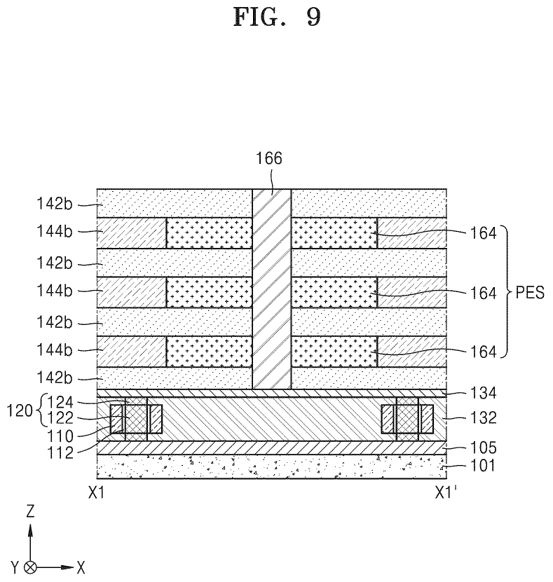

Referring to FIG. 9, in a product of FIGS. 8A and 8B, after forming, at substantially the same position as the first trench T1 described with reference to FIGS. 7A to 7C, a trench (not shown) having the same width in the first horizontal direction (the X direction) as the first trench T1 or a greater width in the first horizontal direction (the X direction) than the first trench T1, the insulation cut pattern 166 filling the trench may be formed. According to some example embodiments, a vertical extension portion of the conductive gap-fill layer 162 may be removed by the trench, and thus, the plurality of plate stacks PES may be formed. For example, two plate stacks PES may face each other in the first horizontal direction (the X direction) with the insulation cut pattern 166 therebetween. For example, each plate stack PES may include three plate electrodes 164 overlapping one another in the vertical direction (the Z direction). The three plate electrodes 164 may be apart from each other in the vertical direction (the Z direction) with one preliminary insulating pattern 142b therebetween.

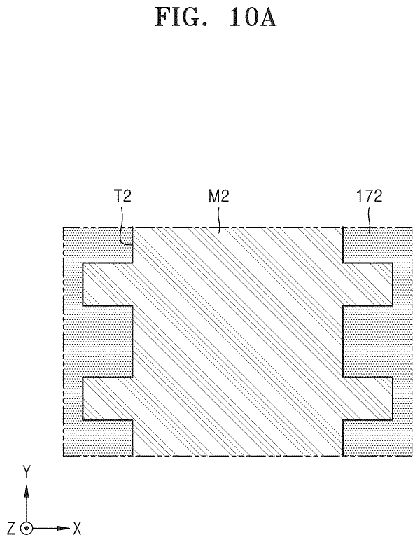

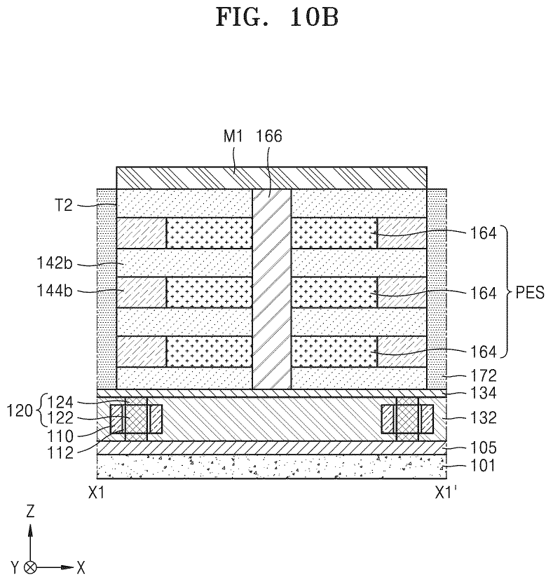

Referring to FIGS. 10A and 10B, after forming a first mask M1 on a product of FIG. 9, the plurality of preliminary insulating patterns 142b and the plurality of first sacrificial patterns 144b may be removed by using the first mask M1 as an etch mask to form a second trench T2.

According to some example embodiments, the second trench T2 may be formed by a dry etch process, and the etch stop layer 134 may be exposed to a bottom surface of the second trench T2. Thereafter, the insulating block 172 filling the second trench T2 may be formed. According to some example embodiments, the insulating block 172 may be in contact with side walls of the plurality of preliminary insulating patterns 142b not removed and remaining, and side walls of the plurality of first sacrificial patterns 144b not removed and remaining.

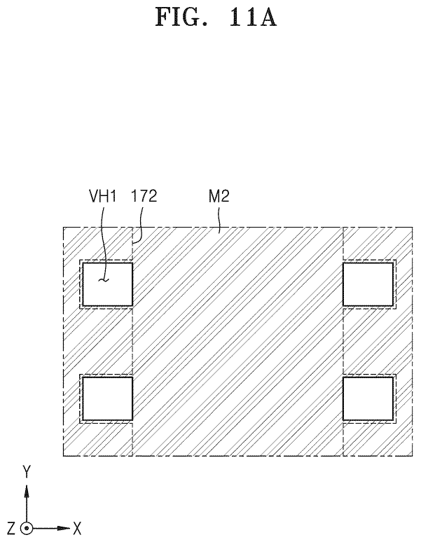

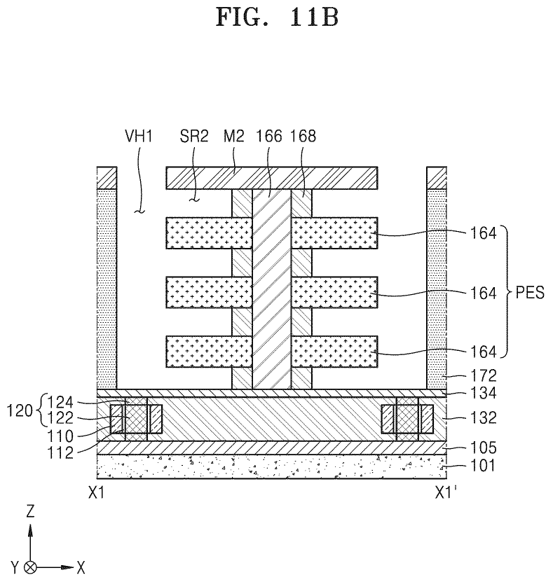

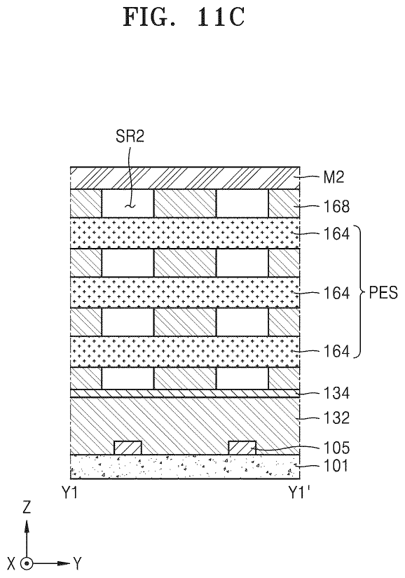

Referring to FIGS. 11A to 11C, in a product of FIGS. 10A and 10B, after removing the first mask M1, a second mask M2 exposing a portion of the plurality of preliminary insulating patterns 142b not removed and remaining may be formed. For example, the second mask M2 may cover upper surfaces of the insulating block 172 and the insulation cut pattern 166.

According to some example embodiments, a plurality of first vertical holes VH1 may be formed through the second mask M2, and the remaining portions of the plurality of first sacrificial patterns 144b and the plurality of preliminary insulating patterns 142b may be removed to form the plurality of insulation support patterns 168. According to some example embodiments, the insulating block 172 may have etch selectivities with respect to the plurality of preliminary insulating patterns 142b and the plurality of first sacrificial patterns 144b, and thus, may not be removed or may be removed by a very small ratio in the process of forming the second horizontal recess SR2. According to some example embodiments, after forming the second trench T2 described with reference to FIGS. 10A and 10B, an insulating liner (not shown) conformally covering an inner wall of the second trench T2 may be formed, and then, the insulating block 172 may be formed on the insulating liner. In this case, the insulating liner may have an etch selectivity with respect to the plurality of preliminary insulating patterns 142b and the plurality of first sacrificial patterns 144b and may perform a function of protecting the insulating block 172 not to be removed in the process of forming the second horizontal recess SR2.

According to some example embodiments, a remaining portion of a surface of the plurality of plate stacks PES, excluding a portion in contact with the plurality of insulation support patterns 168 and a portion in contact with the insulation cut pattern 166, may be exposed through the plurality of first vertical holes VH1 and the second horizontal recess SR2. For example, a side wall toward the first vertical hole VH1 of both side walls of each of the plurality of plate electrodes 164 in the first horizontal direction (the X direction) and an upper portion and a lower portion of each of the plurality of plate electrodes 164 may be exposed.

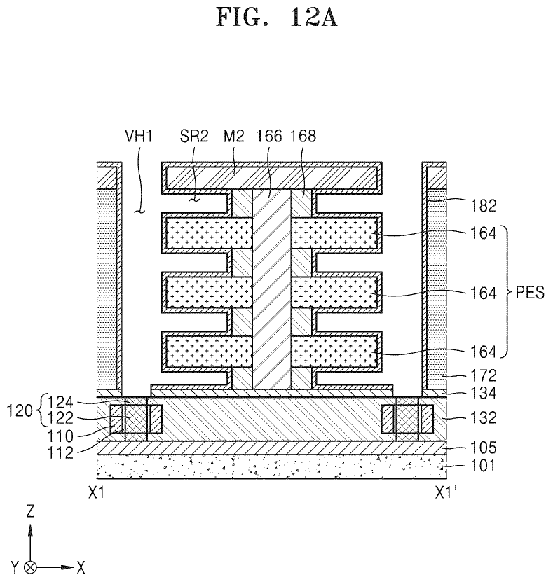

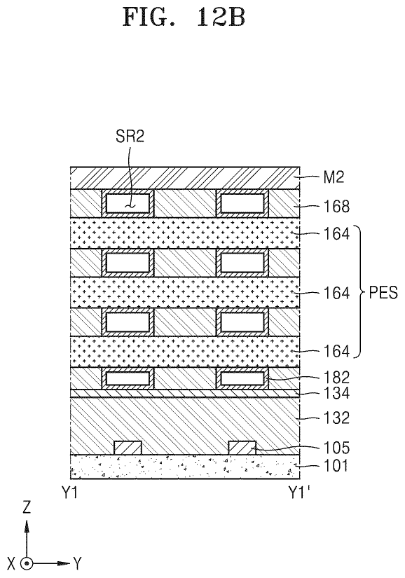

Referring to FIGS. 12A and 12B, the capacitor dielectric layer 182 conformally covering a product of FIGS. 11A to 11C may be formed. The capacitor dielectric layer 182 may cover a surface of the plurality of plate electrodes 164 in the plurality of first vertical holes VH1 and the second horizontal recess SR2 and may cover a surface of the plurality of insulation support patterns 168. Also, the capacitor dielectric layer 182 may cover a portion of the side wall of the insulating block 172 and a portion of the upper surface of the etch stop layer 134, exposed through the plurality of first vertical holes VH1 and the second horizontal recess SR2.

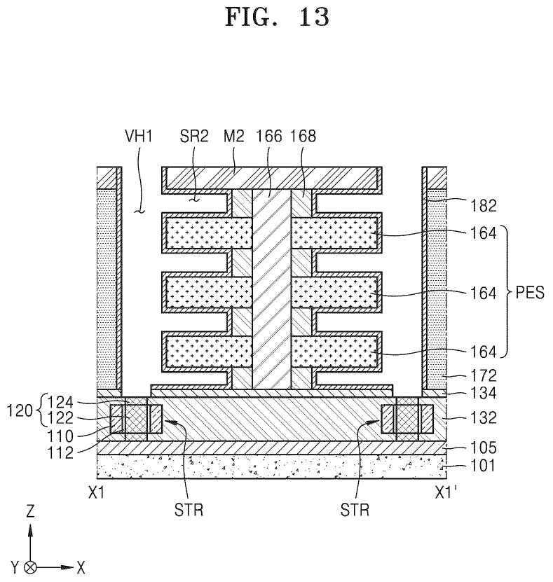

Referring to FIG. 13, in a product of FIGS. 12A and 12B, a portion of the capacitor dielectric layer 182 vertically overlapping the plurality of semiconductor patterns 120 and a portion of the etch stop layer 134 may be removed through the plurality of first vertical holes VH1. Accordingly, an upper surface of the plurality of semiconductor patterns 120 may be exposed.

Referring to FIGS. 13 and 2A to 2E together, a conductive material layer filling the plurality of first vertical holes VH1 and the second horizontal recess SR2 may be formed in a product of FIG. 13. Thereafter, the second mask M2 may be removed by a planarization process to form the plurality of common electrodes 184. According to some example embodiments, before forming the conductive material layer, an impurity doping process may be performed through an exposed upper surface of the semiconductor pattern 120 to form the impurity area 124.

According to some example embodiments, through the planarization process, an upper surface of the uppermost of the horizontal extension portions 184b from among the plurality of horizontal extension portions 184b may be exposed. Thereafter, although not shown, an upper insulating layer (not shown) covering an upper surface of the plurality of horizontal extension portions 184b, an upper surface of the vertical extension portion 184a, an upper surface of the insulation cut pattern 166, an upper surface of the insulation support pattern 168 arranged at the uppermost end form among the plurality of insulation support patterns 168, and an upper surface of the insulating block 172 may be formed to manufacture the memory device 100 described with reference to FIGS. 2A to 2E.

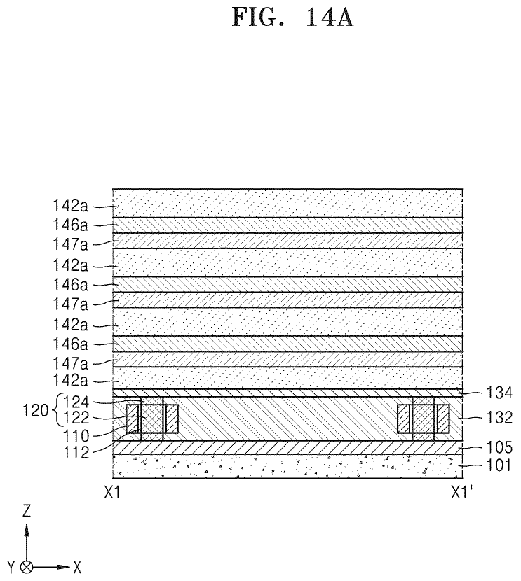

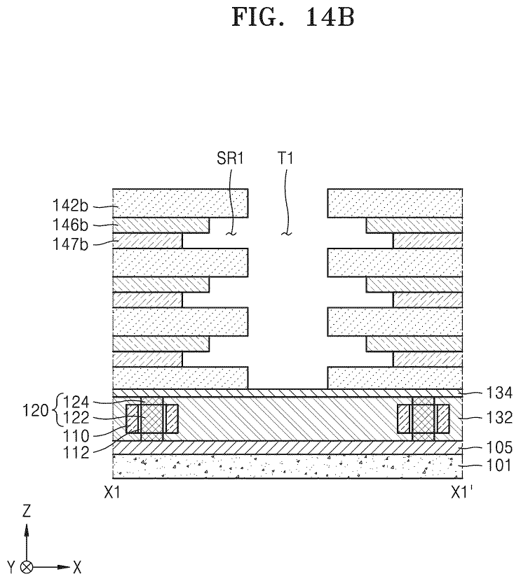

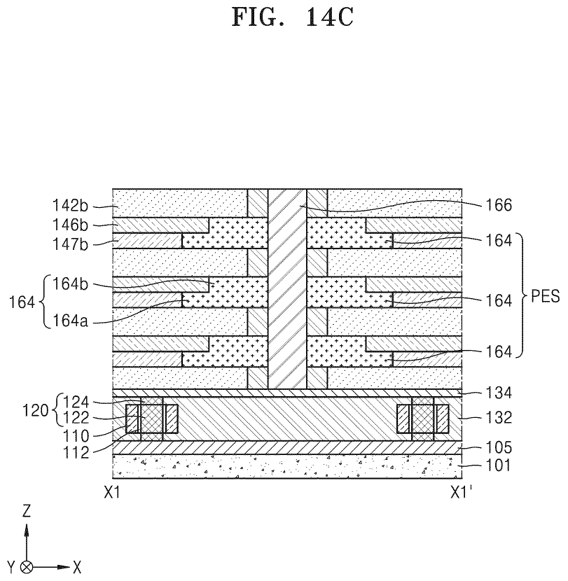

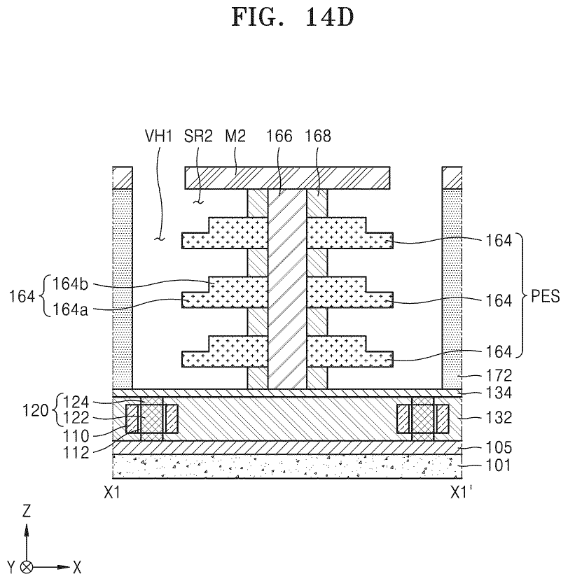

FIGS. 14A to 14D are cross-sectional views for describing a method of manufacturing the memory device 100a, according to some example embodiments, and show a portion corresponding to the cross-section taken along the line X1-X1′ of FIG. 2C. In FIGS. 14A to 14D, reference numerals which are the same as the reference numerals of FIGS. 1, 2A to 2E, 3 and 6A to 13 refer to the same members, and descriptions with respect thereto are not repeatedly given herein.

Referring to FIG. 14A, like the method of manufacturing the memory device 100 described with reference to FIGS. 6A to 13, the method of manufacturing the memory device 100a may include, after forming, on the substrate 101, the plurality of bit lines 105, the plurality of word lines 110, the gate dielectric layer 112, the plurality of semiconductor patterns 120, and the lower insulating layer 132, forming the etch stop layer covering an upper surface of the lower insulating layer 132 and an upper surface of the semiconductor pattern 120.

Thereafter, unlike the method of manufacturing the memory device 100 described with reference to FIGS. 6A to 13, each of a plurality of first insulating layers 142a, each of a plurality of first sacrificial layers 147a, and each of a plurality of second sacrificial layers 146a may be alternately stacked on the etch stop layer 134. For example, one first insulating layer 142a, one first sacrificial layer 147a, and one second sacrificial layer 146a that are sequentially stacked may form one multi-layer structure. For example, the plurality of multi-layer structures may be stacked on the etch stop layer 134.

According to some example embodiments, the plurality of first insulating layers 142a, the plurality of first sacrificial layers 147a, and the plurality of second sacrificial layers 146a may have etch selectivities with respect to one another.

Referring to FIG. 14B, in a product of FIG. 14A, after forming a first trench T1 penetrating through the plurality of multi-layer structures in the vertical direction (the Z direction) and exposing the etch stop layer 134, portions of the plurality of first sacrificial layers 147a and the plurality of second sacrificial layers 146a may be removed to form a first horizontal recess SR1. Accordingly, a plurality of preliminary insulating patterns 142b, a plurality of first sacrificial patterns 147b, and a plurality of second sacrificial patterns 146b may be formed.

According to some example embodiments, in the process of forming the first trench T1, portions of each of the plurality of first insulating layers 142a, the plurality of first sacrificial layers 147a, and the plurality of second sacrificial layers 146a may be removed.

According to some example embodiments, in the etch process of forming the first horizontal recess SR1, the plurality of first sacrificial layers 147a may be removed by a higher etch ratio than the plurality of second sacrificial layers 146a. According to some example embodiments, in the etch process of forming the first horizontal recess SR1, the plurality of first sacrificial layers 147a may be removed by a higher etch ratio than the plurality of second sacrificial layers 146a. According to some example embodiments, in the etch process of forming the first horizontal recess SR1, the plurality of first insulating layers 142a may not be substantially removed or may be removed by a very small ratio.

Due to the differences in etch rate as described above, the plurality of preliminary insulating patterns 142b, the plurality of first sacrificial layers 147a, and the plurality of second sacrificial patterns 146b may have a reverse step difference structure as illustrated in FIG. 14B.

Referring to FIG. 14C, in a product of FIG. 14B, after filling the first trench T1 and the first horizontal recess SR1 with the conductive gap-fill layer 162 (see FIG. 8A), a trench (not shown) having substantially the same width in the first horizontal direction (the X direction) as the first trench T1 may be formed again by removing a portion of the conductive gap-fill layer 162, and then, the insulation cut pattern 166 may be filled in the trench (not shown) to form the plurality of plate stacks PES. According to some example embodiments, each of the plurality of plate electrodes 164 included in each plate stack PES may include the lower portion 164a having a relatively greater width in the first horizontal direction (the X direction) than the upper portion 164b and the upper portion 164b having a relatively less width in the first horizontal direction (the X direction) than the lower portion 164a. According to some example embodiments, the plurality of plate electrodes 164 may have a step difference structure at a side in the first horizontal direction (the X direction). For example, the step difference structure may extend in the second horizontal direction (the Y direction).

Referring to FIG. 14D, in a product of FIG. 14C, as described with reference to FIGS. 10A and 10B, after forming the first mask (M1) (see FIG. 10B), the plurality of preliminary insulating patterns 142b, the plurality of first sacrificial layers 147a, and the plurality of second sacrificial patterns 146b may be removed by using the first mask M1 as an etch mask to form the second trench T2 (see FIG. 10D). Thereafter, the insulating block 172 filling the second trench T2 may be formed.

Thereafter, after removing the first mask M1, a second mask M2 exposing a portion of the plurality of preliminary insulating patterns 142b not removed and remaining may be formed. For example, the second mask M2 may cover upper surfaces of the insulating block 172 and the insulation cut pattern 166. A plurality of first vertical holes VH1 may be formed through the second mask M2, and by removing the remaining portions of the plurality of first sacrificial patterns 147b, the plurality of second sacrificial patterns 146b, and the plurality of preliminary insulating patterns 142b, a second horizontal recess SR2 may be formed. Thus, the plurality of insulation support patterns 168 may be formed. According to some example embodiments, the insulating block 172 may have etch selectivities with respect to the plurality of preliminary insulating patterns 142b, the plurality of first sacrificial patterns 147b, and the plurality of second sacrificial patterns 146b, and thus, may not be removed or may be removed by a very small ratio in the process of forming the second horizontal recess SR2.

According to some example embodiments, in the etch process of forming the second horizontal recess SR2, the plurality of first sacrificial patterns 147b and the plurality of second sacrificial patterns 146b may be entirely removed, and the plurality of preliminary insulating patterns 142b may be partially removed to form the plurality of insulation support patterns 168.

According to some example embodiments, a remaining portion of a surface of the plurality of plate stacks PES, excluding a portion in contact with the plurality of insulation support patterns 168 and a portion in contact with the insulation cut pattern 166, may be exposed through the plurality of first vertical holes VH1 and the second horizontal recess SR2. For example, a side wall having a step difference structure of both side walls of each of the plurality of plate electrodes 164 in the first horizontal direction (the X direction) may be exposed, and an upper portion and a lower portion of each of the plurality of plate electrodes 164 may be exposed.

Referring to FIG. 3and 14D together, the capacitor dielectric layer 182 conformally covering a product of FIG. 14D may be formed. The capacitor dielectric layer 182 may cover a surface of the plurality of plate electrodes 164, a surface of the plurality of insulation support patterns 168, a surface of the insulating block 172, and a surface of the etch stop layer 134 in the plurality of first vertical holes VH1 and the second horizontal recess SR2. Thereafter, by removing a portion of the etch stop layer 134 vertically overlapping the plurality of semiconductor patterns 120 and a portion of the capacitor dielectric layer 182 vertically overlapping the plurality of semiconductor patterns 120, an upper surface of the plurality of semiconductor patterns 120 may be exposed. Thereafter, a conductive material layer filling the plurality of first vertical holes VH1 and the second horizontal recess SR2 may be formed, and then, the second mask M2 may be removed through planarization to form the memory device 100a.

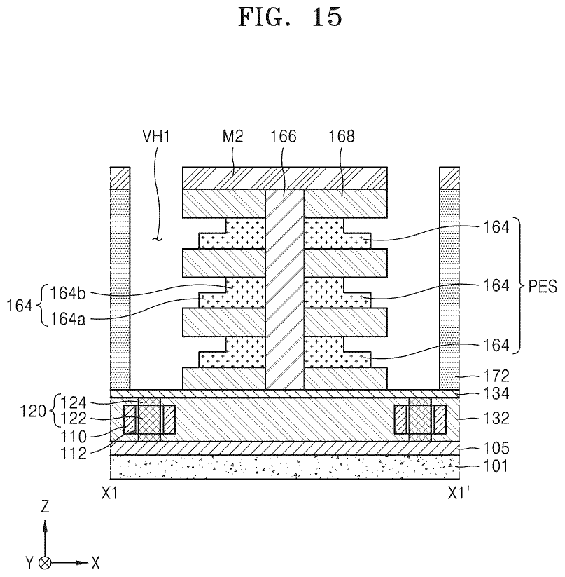

FIG. 15 is a cross-sectional view for describing a method of manufacturing the memory device 100b, according to some example embodiments, and shows a portion corresponding to the cross-section taken along the line X1-X1′ of FIG. 2C. In the description below with respect to the method of manufacturing the memory device 100b with reference to FIG. 15, reference numerals which are the same as the reference numerals of FIGS. 1, 2A to 2E, 3 and 4, and 6A to 13 refer to the same members, and descriptions with respect thereto are not repeatedly given herein.

Referring to FIG. 15, the method of manufacturing the memory device 100b, according to various example embodiments, may include substantially the same method as the method described with reference to FIGS. 14A to 14D, except that in the method of manufacturing the memory device 100b of FIG. 15, a very small portion of the plurality of preliminary insulating patterns 142b may be removed in the process of forming the second horizontal recess SR2 described with reference to FIG. 14C to form the insulation support patterns 168 having a relatively greater width in the first horizontal direction (the X direction) than the insulation support patterns 168 of the memory device 100a.

According to some example embodiments, in the etch process of forming the second horizontal recess SR2, the plurality of first sacrificial patterns 147b and the plurality of second sacrificial patterns 146b may be removed by a higher etch ratio than the plurality of preliminary insulating patterns 142b. According to some example embodiments, the plurality of preliminary insulating patterns 142b may not be substantially removed or a very small amount of the same may be removed to form the plurality of insulation support patterns 168. Thus, the plurality of insulation support pattern 168 may cover an upper surface and a lower surface of the plurality of plate electrodes 164. Referring to FIG. 15, the second horizontal recess SR2 may be defined by a portion of an upper surface and a portion of lower surface of the plurality of insulation support patterns 168 and a side wall of the plurality of plate electrodes 164.

Thereafter, as described with reference to FIGS. 14D and 3 together, the capacitor dielectric layer 182 conformally covering a plurality of first vertical holes VH1 and an inner wall of the second horizontal recess SR2 may be formed, and then, a portion of the etch stop layer 134 vertically overlapping the plurality of semiconductor patterns 120 and a portion of the capacitor dielectric layer 182 vertically overlapping the plurality of semiconductor patterns 120 may be removed to expose an upper surface of the plurality of semiconductor patterns 120. Thereafter, a conductive material layer filling the plurality of first vertical holes VH1 and the second horizontal recess SR2 may be formed, and then, the second mask M2 may be removed through planarization to form the memory device 100b.

While the inventive concept has been particularly shown and described with reference to example embodiments thereof, it will be understood that various changes in form and details may be made therein without departing from the spirit and scope of the following claims.

What is claimed is:

1. A memory device comprising:
a substrate;
a unit cell selection transistor on the substrate; and
a capacitor structure on the unit cell selection transistor, the capacitor structure comprising a common electrode connected to the unit cell selection transistor, a plurality of plate electrodes facing the common electrode, and a capacitor dielectric layer arranged between the common electrode and the plurality of plate electrodes,
wherein the common electrode comprises
a vertical extension portion in contact with the unit cell selection transistor and extending in a vertical direction, and
a plurality of horizontal extension portions extending in a first horizontal direction from a side wall of the vertical extension portion and apart from each other in the vertical direction, and
wherein each of the plurality of plate electrodes extends in a second horizontal direction between the plurality of horizontal extension portions, the second horizontal direction being perpendicular to the first horizontal direction.

2. The memory device of claim 1, wherein the plurality of horizontal extension portions comprises:
a first horizontal extension portion facing an upper surface of a plate electrode from among the plurality of plate electrodes with the capacitor dielectric layer therebetween; and
a second horizontal extension portion spaced apart from the first horizontal extension portion, in the vertical direction, with the plate electrode therebetween, the second horizontal extension portion facing a lower surface of the plate electrode with the capacitor dielectric layer therebetween.

3. The memory device of claim 1, wherein a side wall of each of the plurality of plate electrodes in the first horizontal direction faces the side wall of the vertical extension portion, with the capacitor dielectric layer therebetween.

4. The memory device of claim 1, further comprising an insulating structure surrounding the capacitor structure,
wherein both side walls of each of the plurality of horizontal extension portions in the second horizontal direction are in contact with the insulating structure.

5. The memory device of claim 1, wherein the plurality of horizontal extension portions and the plurality of plate electrodes are arranged at different vertical levels from each other.

6. The memory device of claim 1, wherein the capacitor dielectric layer comprises ferroelectrics.

7. The memory device of claim 1, wherein each of the plurality of plate electrodes comprises:
a lower portion; and
an upper portion on the lower portion, the upper portion having a less width in the first horizontal direction than the lower portion,
wherein a side wall of the lower portion in the first horizontal direction and a side wall of the upper portion in the first horizontal direction are co-planar with each other, and
each of the plurality of plate electrodes has a stepped side wall.

8. The memory device of claim 7, wherein each of the plurality of horizontal extension portions comprises a portion arranged at a same vertical level as the upper portion of each of the plurality of plate electrodes.

9. The memory device of claim 7, wherein the other side wall of the upper portion in the first horizontal direction faces one horizontal extension portion from among the plurality of horizontal extension portions, in the first horizontal direction, and
the other side wall of the lower portion in the first horizontal direction faces the vertical extension portion, in the first horizontal direction.

10. The memory device of claim 1, further comprising:
an etch stop layer on the unit cell selection transistor, the etch stop layer covering an upper surface of the substrate,
wherein the vertical extension portion penetrates through the etch stop layer and is in contact with the unit cell selection transistor.

11. A memory device comprising:
a substrate;
a plurality of bit lines extending on the substrate in a first horizontal direction and apart from each other in a second horizontal direction perpendicular to the first horizontal direction;
a plurality of unit cell selection transistors arranged on the plurality of bit lines, respectively;
a plurality of common electrodes arranged on the plurality of unit cell selection transistors to be apart from each other in the second horizontal direction, the plurality of common electrodes each comprising a vertical extension portion and a plurality of horizontal extension portions extending in the first horizontal direction from a side wall of the vertical extension portion;
a plurality of capacitor dielectric layers encircling the plurality of common electrodes, respectively; and
a plurality of plate electrodes respectively facing, with the plurality of capacitor dielectric layers therebetween, the plurality of common electrodes, the plurality of plate electrodes extending in the second horizontal direction and overlapping each other in a vertical direction,
wherein each of the plurality of plate electrodes comprises a first end and a second end that are opposite to each other in the first horizontal direction, wherein the first end has a stepped side wall shape, and the second end has a side wall shape linearly extending in the vertical direction, and
the plurality of common electrodes face the first end.

12. The memory device of claim 11, wherein each of the plurality of horizontal extension portions alternately overlaps each of the plurality of plate electrodes in the vertical direction.

13. The memory device of claim 11, wherein the plurality of horizontal extension portions comprise a first horizontal extension portion extending between a first plate electrode and a second plate electrode adjacent to each other from among the plurality of plate electrodes.

14. The memory device of claim 11, wherein the first end comprises a portion facing the side wall of the vertical extension portion.

15. The memory device of claim 11, wherein each of the plurality of horizontal extension portions is arranged at a same vertical level as one plate electrode selected from among the plurality of plate electrodes.

16. The memory device of claim 11, further comprising an insulating structure encircling, on the substrate, the plurality of capacitor dielectric layers and the plurality of plate electrodes,
wherein the first end vertically overlaps the insulating structure in the vertical direction.

17. A memory device comprising:
a substrate;
a bit line extending on the substrate in a first horizontal direction;
a plurality of semiconductor patterns arranged on the bit line to be apart from each other in the first horizontal direction;
a plurality of word lines covering side surfaces of the plurality of semiconductor patterns, respectively, and extending in a second horizontal direction perpendicular to the first horizontal direction;
a plurality of common electrodes arranged on the plurality of semiconductor patterns, wherein each of the plurality of common electrodes comprises a vertical extension portion extending in a vertical direction and a plurality of horizontal extension portions extending in the first horizontal direction from a side wall of the vertical extension portion and apart from each other in the vertical direction;
a plurality of plate electrodes, each of the plate electrodes are arranged between the plurality of horizontal extension portions, and extend in the second horizontal direction, and
a plurality of capacitor dielectric layers between the plurality of common electrodes and the plurality of plate electrodes,
wherein a first common electrode and a second common electrode adjacent to each other in the first horizontal direction, from among the plurality of common electrodes, have mirror symmetrical shapes with respect to each other.

18. The memory device of claim 17, further comprising an insulating structure arranged between the first common electrode and the second common electrode,
wherein a first group from among the plurality of plate electrodes, the first group facing the first common electrode, is apart, in the first horizontal direction, with the insulating structure therebetween, from a second group from among the plurality of plate electrodes, the second group facing the second common electrode.

19. The memory device of claim 18, wherein the first group from among the plurality of plate electrodes faces the side wall of the vertical extension portion of the first common electrode, and
the second group from among the plurality of plate electrodes faces the side wall of the vertical extension portion of the second common electrode.

20. The memory device of claim 17, wherein the plurality of horizontal extension portions comprise a first horizontal extension portion and a second horizontal extension portion that are apart from each other in the vertical direction with a plate electrode from among the plurality of plate electrodes therebetween,
an upper surface of the plate electrode faces a lower surface of the first horizontal extension portion, and
a lower surface of the plate electrode faces an upper surface of the second horizontal extension portion.
